(19) United States
(12) Patent Application Publication
(10) Pub. No.: US 2014/0069493 A1
(43) Pub. Date: Mar. 13, 2014

(54) PHOTOVOLTAIC DEVICE

(71) Applicant: Alliance for Sustainable Energy, LLC, Golden, CO (US)

(72) Inventors: Kirstin Alberi, Golden, CO (US); Angelo Mascarenhas, Golden, CO (US); Mark W. Wanlass, Golden, CO (US)

(73) Assignee: Alliance for Sustainable Energy, LLC, Golden, CO (US)

(21) Appl. No.: 14/115,332

(22) PCT Filed: May 7, 2012
(86) PCT No.: PCT/US12/36788

§ 371 Date: Nov. 1, 2013

Related U.S. Application Data
(60) Provisional application No. 61/483,480, filed on May 6, 2011.

(51) Int. Cl. H01L 31/0735; H01L 31/074; H01L 31/18; H01L 31/0725

(52) U.S. Cl. CPC H01L 31/0735; H01L 31/0725; H01L 31/074; H01L 31/1844
USPC 136/255; 136/252; 136/262; 438/94

(57) ABSTRACT

A multijunction photovoltaic device (300) is provided. The multijunction photovoltaic device (300) includes a substrate (301) and one or more intermediate sub-cells (303a-303c) coupled to the substrate (301). The multijunction photovoltaic device (300) further includes a top sub-cell (304) comprising an AlₓIn₁₋ₓP alloy coupled to the one or more intermediate sub-cells (303a-303c) and lattice mismatched to the substrate (301).

### CROSS REFERENCE

This application claims priority from U.S. Provisional Patent Application No. 61/483,480, filed May 6, 2011, entitled “Multijunction Solar Cell Devices and Fabricating Methods Thereof”, the contents of which are incorporated herein by reference.

### CONTRACTUAL ORIGIN

The United States Government has rights in this invention under Contract No. DE-AC36-08GO28308 between the United States Department of Energy and the Alliance for Sustainable Energy, LLC, the Manager and Operator of the National Renewable Energy Laboratory.

### BACKGROUND

Due in part to the increased cost associated with non-renewable energy as well as increased environmental concerns, many consumers are relying on renewable energy sources such as photovoltaic solar panels. Photovoltaic solar panels convert solar energy into electrical energy. The efficiency of single p-n junction solar cells is relatively limited by its inability to convert a sufficient portion of the solar spectrum into usable energy. For example, photons below the bandgap of the cell material pass through the cell without creating electron-hole pairs. Photon energy above the bandgap energy are absorbed, but the excess energy is lost in the form of thermal energy, as only the energy necessary to generate the electron-hole pair is converted to useful energy.

Solar cells comprising more than one p-n junction are typically referred to as multijunction solar cells while solar cells with a single p-n junction are typically referred to as single junction solar cells. Multijunction or multi-gap photovoltaic devices are promising, as they use a number of p-n junctions (referred to as sub-cells in the present description) to increase the total portion of the solar spectrum that is efficiently absorbed and to reduce thermalization losses. The greater the number of sub-cells utilized in a photovoltaic device, the smaller these losses become.

Another consideration in providing multiple sub-cells is that they are typically connected in series. In this configuration, the current of the photovoltaic device is limited by the sub-cell having the lowest current, and the voltages of the sub-cells. The total power output of the device is then optimized by balancing the current and voltage characteristics of the sub-cells.

In many designs, the sub-cells are grown in a heteroepitaxial manner, which can lead to strain if the sub-cells are not properly lattice matched to one another. Consequently, the materials used in prior art systems were often selected in order to reduce the strain and maximize the lattice matching. However, such limitations do not necessarily result in optimal bandgap energies for the various sub-cells.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools, and methods which are meant to be exemplary and illustrative, not limiting in scope. In various embodiments, one or more of the above-described problems have been reduced or eliminated, while other embodiments are directed to other improvements.

A multijunction photovoltaic device is provided according to an embodiment comprising a substrate and one or more intermediate sub-cells coupled to the substrate. According to an embodiment, the multijunction photovoltaic device further comprises a top sub-cell comprising an AlₓIn₁₋ₓP alloy coupled to the one or more intermediate sub-cells which is lattice mismatched to the substrate.

A single junction photovoltaic device is provided according to an embodiment includes a substrate and a transitional buffer layer coupled to the substrate. According to the disclosed exemplary embodiment, the single junction photovoltaic device further comprises a p-n junction comprising an AlₓIn₁₋ₓP alloy coupled to the transitional buffer layer.

A method for forming a multijunction photovoltaic device comprises a first step of providing a substrate. The method further comprises a step of forming one or more intermediate sub-cells on top of the substrate. According to an exemplary embodiment disclosed herein, the method further comprises a step of forming a top sub-cell comprising an AlₓIn₁₋ₓP alloy on top of the one or more intermediate sub-cells that is lattice mismatched to the substrate.

An exemplary method for forming a single junction photovoltaic device is also provided comprising a step of providing a substrate, the step of coupling a transitional buffer layer to the substrate and the step of forming a p-n junction comprising an AlₓIn₁₋ₓP alloy coupled to the transitional buffer layer.

In addition to the exemplary aspects and embodiments described above, further aspects and embodiments will become apparent by reference to the drawings and by study of the following descriptions.

### BRIEF DESCRIPTION OF THE DRAWINGS

Exemplary embodiments are illustrated in referenced figures of the drawings. It is intended that the embodiments and figures disclosed herein are to be considered illustrative rather than limiting.

FIG. 1 illustrates a graph of the photoluminescence spectrum of Al₁In₁₋ₓP emitted near 2 eV.

FIG. 2 illustrates a plot of the bandgap energies of many III-V semiconductor alloys, as a function of their lattice constants with the general lattice constant span and ideal bandgap ranges targeted for exemplary sub-cells superimposed thereon.

FIG. 3 illustrates a schematic diagram of an exemplary multijunction photovoltaic bottom-up fabrication approach.

FIG. 4 illustrates a schematic diagram of an exemplary multijunction photovoltaic inverted fabrication approach.

FIG. 5 illustrates another schematic diagram of an exemplary multijunction photovoltaic fabrication approach after the device has been coupled to a substrate.

FIG. 6 illustrates another schematic diagram of an exemplary multijunction photovoltaic bottom-up fabrication approach.

FIG. 7 illustrates another schematic diagram of an exemplary single-junction photovoltaic fabrication approach.

### DETAILED DESCRIPTION

FIGS. 1-7 and the following description depict specific examples to teach those skilled in the art how to make and use the best mode of embodiments of a photovoltaic device. For the purpose of teaching inventive principles, some conventional aspects have been simplified or omitted. Those skilled in the art will appreciate variations from these examples that fall within the scope of the present description. Those skilled in the art will also appreciate that the features described below can be combined in various ways to form multiple variations of the disclosed exemplary implementations of a photovoltaic device. As a result, the embodiments described below are not limited to the specific examples described below, but only by the claims and their equivalents.

The design of multijunction photovoltaic devices may involve various performance requirements depending on the particular application. For example, according to an embodiment, the bandgap energies (E_{g}) of each of the sub-cells may be optimized together to produce the highest overall efficiencies. In the case of a series-connected device, increasing the number of sub-cells may improve the operating voltage and efficiency. As mentioned above, increasing the number of junctions may adversely affect the current; however, the improved operating voltage can offset the adverse effects to the current. In some embodiments, the beneficial effect of an improved operating voltage may be greater than that of the reduced current such that the overall power output increases. According to another embodiment, another method to optimize power output may be to increase the bandgap energy of the top sub-cell. For example, the high voltage, low current conditions obtained by raising the bandgaps of the sub-cells may be beneficial for reducing joule losses under high solar concentration conditions. Table 1 is an exemplary embodiment outlining desirable bandgap energies for 2, 3, 4 and 5 sub-cell architectures with a constrained bottom sub-cell E_{g}=0.9 eV (electron volt) based on calculations assuming a series-connected device under an AOD85 spectrum (terrestrial concentration, 500 suns, 50 C). It should be appreciated that the values provided in Table 1 are merely illustrative and should in no way limit the scope of the exemplary embodiments disclosed herein.

TABLE 1

| # of sub- | E_{g1} | E_{g2} | | | | Efficiency |
|---|---|---|---|---|---|---|
| cells | (eV) | (eV) | E_{g3} (eV) | E_{g4} (eV) | E_{g5} (eV) | (%) |
| 2 | 1.54 | 0.94 | | | | 37.7 |
| 3 | 1.86 | 1.34 | 0.90 | | | 42.1 |
| 4 | 2.03 | 1.56 | 1.21 | 0.92 | | 44.6 |
| 5 | 2.16 | 1.73 | 1.42 | 1.16 | 0.92 | 46.3 |

As can be appreciated from Table 1, as the number of sub-cells with optimal bandgap energies increases, the efficiency of the photovoltaic device increases.

According to the exemplary embodiment, the monolithic fabrication of a device via epitaxial growth of the sub-cells on a single substrate may generally necessitate that the sub-cell materials be grown under strain-free conditions in order to prevent the formation of strain-induced defects during fabrication. Thus, the sub-cells may necessarily be lattice-matched to one another and possibly to the substrate as well. Lattice-matching in the present implementation means that the difference in lattice constants between adjacent layers is insufficient to induce strain relaxation through dislocation formation. Defects caused by lattice-mismatched layers, such as dislocations, may tend to act as non-radiative recombination sites for photo-generated carriers, limit minority carrier diffusion lengths, and lower the output power. Accordingly, it may be desirable to limit defects during fabrication.

Several approaches to fabricating III-V semiconductor-based multijunction photovoltaic devices exist. Many common approaches utilize a Germanium (Ge) (lattice constant, a=0.5657 nm) or a Gallium Arsenide (GaAs) (a=0.5653 nm) substrate. One implementation uses three lattice-matched sub-cells: Ge (0.66 eV), GaAs (E_{g}=1.43 eV) and Indium Gallium Phosphide (Ga_{0.51}In_{0.49}P) (E_{g}=1.85 eV). However, the un-optimized bandgap energies may limit the performance of such a device. In particular, the high photon absorption in the thick Ge wafer may hinder the voltage and power output optimization efforts in series-connected devices. Another device implementation replaces the Ge sub-cell with Gallium Indium Arsenide (Ga_{0.7}In_{0.3}As) (E_{g}=0.9 eV). According to the exemplary embodiment, higher bandgaps may also be targeted for the top sub-cell to improve the voltage of the multijunction photovoltaic device, limit joule losses, and improve the efficacy of antireflection coatings.

Gallium in the GaₓIn₁₋ₓP top sub-cell can be replaced (or at least partially replaced) with Aluminum (Al), to increase the bandgap without significantly changing the lattice constant. As those skilled in the art will appreciate, the tendency of Al to react with oxygen and other impurities has led to a reluctance to add it in high concentrations to any of the sub-cells, and a high bandgap GaₓIn₁₋ₓP (x>0.51) has generally been used in the prior art instead. However, this choice of materials may reduce the bandgap-related losses, but the lattice matching conditions are no longer met. For example, Ga_{0.7}In_{0.3}As (a=0.578 nm) has a larger lattice constant than GaAs and GaₓIn₁₋ₓP (x<0.50, a<0.5657) has a smaller lattice constant. Thus, this approach may have the added complexity of necessitating thick graded transitional buffer layers between the sub-cells to accommodate the large swing in lattice constants without creating unnecessarily high dislocation densities in the sub-cells themselves. Such a device may be fabricated in an inverted metamorphic structure, which is described in U.S. patent application Ser. No. 2006/0144435 filed July, 2006, entitled High-Efficiency, Monolithic, Multi-Bandgap, Tandem Photovoltaic Energy Converters, where the top and intermediate sub-cells with lattice constants close to the GaAs or Ge substrate are grown first, followed by a graded transitional buffer and the layers of the lattice-mismatched sub-cell, thereby minimizing lattice-mismatch induced defects in the bottom cells. The entire structure is then bonded to a foreign handle, and the original substrate is removed, leaving the device in the correct orientation. Serial No. 2006/0144435 is incorporated by reference herein for all that it teaches,

According to an exemplary embodiment, some of the drawbacks associated with the above-mentioned designs can be overcome by providing multijunction photovoltaic devices with two or more sub-cells, in which the top sub-cell is composed of a direct bandgap Aluminum Indium Phosphide (AlₓIn₁₋ₓP) alloy (a>0.565 nm, x<0.45), which is higher than prior GaₓIn₁₋ₓP alloy devices. AlₓIn₁₋ₓP has the highest direct to indirect bandgap transition energy and will produce a top sub-cell with the higher direct bandgaps (e.g., E_{g}>2.0 eV) necessary to optimize the performance of the devices containing two or more sub-cells. Throughout the discussion, various alloys of AlₓIn₁₋ₓP are specifically mentioned that include some Ga and As, but are a departure from the lattice-matched GaₓIn₁₋ₓP and the Al_{y}GaₓIn_{1-x-y}P approaches. Therefore, it should be appreciated that the AlₓIn₁₋ₓP may include other elements that are not specifically listed as those skilled in the art will readily appreciate.

According to an exemplary embodiment, one or more of the lower sub-cells (E_{g}<E_{g} AlₓIn₁₋ₓP), may be lattice-matched to the AlₓIn₁₋ₓP top sub-cell, and the entire structure may be grown strain free on a GaAs or Ge substrate via the use of a single intermediate transitional buffer layer. The transitional buffer layer may comprise a compositionally transitional buffer layer or some other type of transitional buffer layer. In some implementations, all of the lower sub-cells may be lattice-matched to the AlₓIn₁₋ₓP top sub-cell. Consequently, because the sub-cells are lattice-matched, a transitional buffer is not required between the sub-cells. Rather, according to an exemplary embodiment, a transitional buffer can be provided between the bottom sub-cell and the substrate, if necessary. According to another exemplary embodiment, the lower sub-cells may be lattice-matched to the substrate and the AlₓIn₁₋ₓP top sub-cell may be lattice-mismatched to the substrate as well as the lower sub-cells. This embodiment still only requires a single transitional buffer, but it is positioned between the top sub-cell and the lower sub-cells. As those skilled in the art can readily recognize, the necessity and design of the buffer layer may depend on the particular substrate used. In some exemplary embodiments, a buffer layer may not be required and thus, the claims that follow should in no way be limited to requiring a buffer layer. In yet other exemplary embodiments, the top sub-cell may be lattice-matched to one or more intermediate sub-cells while a bottom sub-cell is lattice-mismatched to the remaining sub-cells. In such an embodiment, a transitional buffer layer may be provided between the bottom sub-cell and the intermediate sub-cells and no buffer layer may be required between the bottom sub-cell and the substrate.

According to an exemplary implementation, the multijunction photovoltaic device can take advantage of the higher direct bandgap of AlₓIn₁₋ₓP (x<0.45) to increase the bandgap of the top sub-cell above 1.75 eV. It should be appreciated however, that the top sub-cell is not limited to having a bandgap above 1.75 eV and other bandgaps may be utilized. According to an exemplary implementation, the top sub-cell comprises a bandgap greater than any of the remaining sub-cells. This configuration is an improvement over multijunction photovoltaic device architectures utilizing a lattice-matched Ga_{0.51}In_{0.49}P top sub-cell because the top sub-cell has a larger E_{g}. FIG. 1 shows the photoluminescence spectra of an AlₓIn₁₋ₓP film grown by metal organic chemical vapor deposition (MOCVD) on a GaAs substrate/buffer layer structure according to an embodiment, demonstrating the feasibility of fabricating high quality top sub-cell material with bandgap energies near or above 2 eV. As can be seen in FIG. 1, the photoluminescence peaks around 2 eV when the film is at approximately 295 degrees K.

The top sub-cell design utilizing direct bandgap AlₓIn₁₋ₓP is also an improvement over a metamorphic GaₓIn₁₋ₓP (with no Al) top sub-cell, because it enables highly efficient designs with two or more sub-cells, as shown in Table 1, and has only a small lattice mismatch to GaAs or Ge. As discussed in more detail below, strain-free AlₓIn₁₋ₓP (a>0.565 nm) may also be grown on GaAs or Ge substrates via an intermediate transitional buffer layer grown in compression rather than in tension (in the case of high bandgap GaₓIn₁₋ₓP with x>0.50). The transitional buffer layer may comprise a variety of well-known buffer layers. For example, the transitional buffer layer may comprise GaₓIn₁₋ₓAs; GaSbₓAs₁₋ₓ; GaₓIn₁₋ₓP; etc. The particular transitional buffer layer used should in no way limit the scope of the present exemplary embodiment.

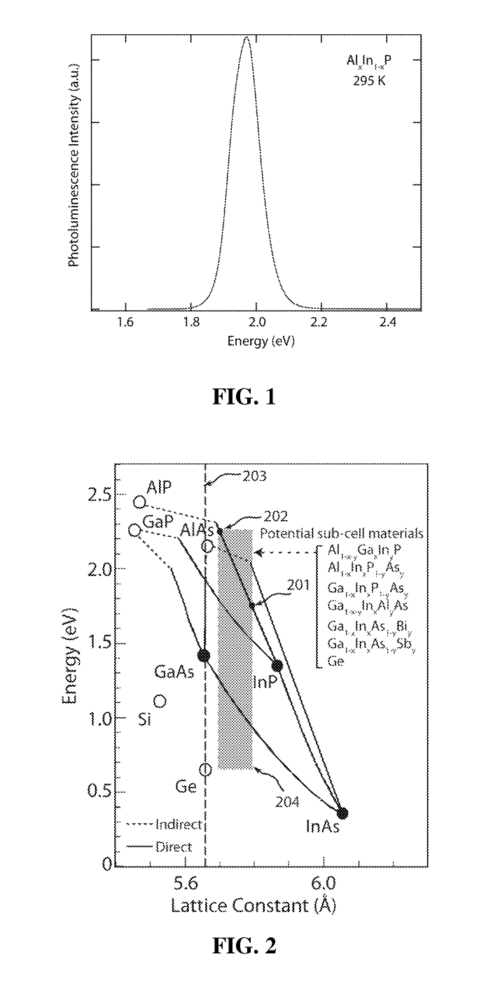

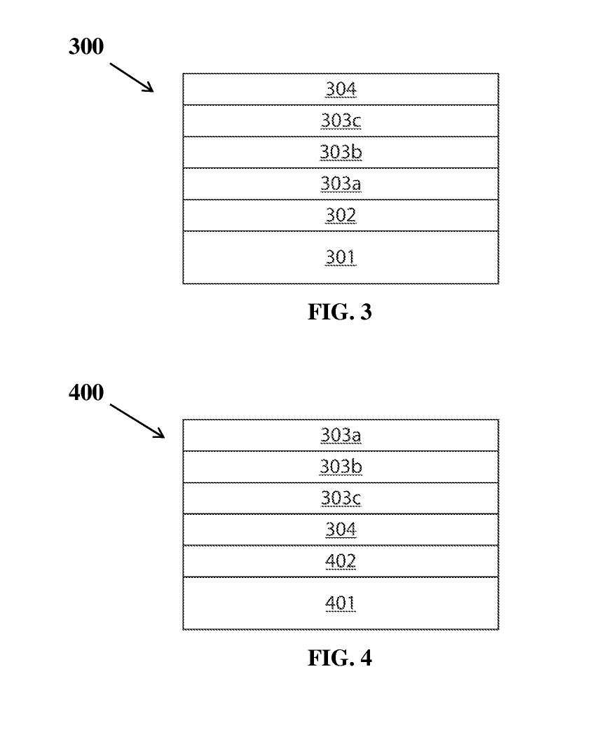

Another advantage of using AlₓIn₁₋ₓP (x<0.45) is that it is lattice-matched to a number of material systems spanning a range of bandgaps that are ideal for other sub-cells in multijunction photovoltaic devices. Thus, an AlₓIn₁₋ₓP top sub-cell permits the design of an optimal multijunction photovoltaic device in which all other sub-cells can be lattice-matched to one another. According to the preferred embodiment, the targeted lattice constant range is roughly 0.57-0.58 nm, as shown in FIG. 2 along with the bandgap energy ranges of interest. However, other lattice constants may be targeted without departing from the scope of the present exemplary embodiment. This approach is an improvement over designs utilizing an (AlₓGa₁₋ₓ)_{0.51}In_{0.49}P top cell that is lattice-matched to a GaAs or Ge substrate because it provides the flexibility to choose semiconductor alloys for the intermediate sub-cells that are both lattice-matched to the top sub-cell and have optimal bandgap energies.

FIG. 2 shows an exemplary list of potential materials that meet these conditions and are also listed Table 2. This list is not meant to be exhaustive, but is included to provide a simple guide of various possible options. The calculations were carried out by the method proposed by T. H. Glisson et al., J. Electron Mater., 7, 1 (1978) with parameters compiled by Vurgaftmann et al., J. Appl. Phys., 89, 5815 (2001).

As shown in FIG. 2, for AlₓIn₁₋ₓP, when the concentrations are adjusted to have a bandgap between approximately point 201 (approximately 1.75 eV) and point 202 (approximately 2.26 eV), the lattice constant is between the 0.57-0.58 nm range. Further, as is shown by the solid line for this segment, the sub-cell has a direct bandgap. Direct bandgap materials absorb photons with energy >E_{g} with much more efficiency than indirect bandgap materials and are therefore much more suitable for the light-absorbing layers of the sub-cell. For example, AlₓIn₁₋ₓP alloys with E_{g}>2.26 eV (x>0.45) have indirect bandgaps and are typically used as a window layer for minority carrier confinement rather than an absorption layer.

Additionally shown in FIG. 2 is the vertical line 203, which is at approximately 0.565 nm. It intersects all alloys bandgap tie lines at compositions that have a lattice constant of 0.565 nm. The line 203 passes close to both GaAs and Ge (potential substrates). However, as can be seen, the line 203 passes through a composition of AlₓIn₁₋ₓP (x≈0.5) with an indirect bandgap. Therefore, if a top sub-cell composed of Al_{0.5}In_{0.5}P were lattice-matched to either GaAs or Ge, it would not very efficiently absorb photons with energy greater than E_{g}. According to an embodiment, the composition of the sub-cells composed of AlₓIn₁₋ₓP can be adjusted such that the bandgaps are direct and the lattice constants are increased into the preferred region outlined as 204. According to an embodiment, the top and intermediate sub-cells can be lattice-matched to one another while being grown strain-free on a lattice-mismatched substrate via a transitional buffer described above.

Table 2 shows the compositions of exemplary quaternary alloys that meet the listed energies and lattice constants.

TABLE 2

| | | a = 5.725 | | a = 5.775 | |
|---|---|---|---|---|---|
| Composition | Eg (eV) | x | y | x | y |
| Al₁₋ₓInₓP_{1-y}As_{y} | 2.1 | 0.48 | 0.35 | 0.48 | 0.55 |
| | 1.9 | 0.53 | 0.22 | 0.56 | 0.45 |
| Al_{1-x-y}GaₓIn_{y}P | 2.1 | 0.07 | 0.64 | | |
| | 1.9 | 0.28 | 0.65 | 0.76 | 0 |
| Ga₁₋ₓInₓP_{1-y}As_{y} | 1.6 | 0.55 | 0.3 | | |
| | 1.3 | 0.27 | 0.85 | 0.52 | 0.58 |
| Ga_{1-x-y}InₓAl_{y}As | 1.6 | 0.17 | 0.72 | 0.29 | 0.3 |
| | 1.3 | 0.18 | 0.03 | 0.3 | 0.12 |
| Ga₁₋ₓInₓAs_{1-y}Bi_{y} | 1.15 | 0.13 | 0.03 | | |
| | 0.9 | 0.04 | 0.08 | 0.17 | 0.08 |
| Ga₁₋ₓInₓAs_{1-y}Sb_{y} | 1.15 | 0.02 | 0.15 | | |

The bandgap of the AlₓIn₁₋ₓP alloy may be dependent on the degree of spontaneous ordering of the Al and In atoms on the group III sub-lattice. The degree of ordering may be tuned in order to slightly adjust the bandgap energy, lattice constant or both when optimizing the design of the sub-cells. According to the exemplary embodiment, a small amount of Ga or As may also be added to AlₓIn₁₋ₓP alloy to slightly adjust the bandgap and/or lattice constant, although quaternary alloys may present additional difficulties that may degrade the device performance. According to the exemplary embodiment, disordered AlₓIn₁₋ₓP that has an indirect bandgap and is lattice-matched to ordered AlₓIn₁₋ₓP having a direct bandgap may be used as a window layer as is generally known in the art.

When the higher bandgap AlₓIn₁₋ₓP top sub-cell is combined with a bottom sub-cell with a bandgap at approximately 0.9 eV and optimally designed middle sub-cells according to Table 1 and shown in FIG. 2, the total multijunction photovoltaic device may operate at a higher voltage and lower current compared to prior art photovoltaic devices that do not incorporate aluminum in the top sub-cell, which has several advantages. Shifting the bandgap energies of all sub-cells to higher values reduces thermal losses. When the energy of an absorbed photon is much greater than the sub-cell bandgap, that excess energy is lost to phonons that heat the device. Therefore, increasing the sub-cell bandgap energies reduces the total amount of energy lost in this manner. An additional advantage of the high operating voltage is the reduction of joule losses. Lower overall current densities significantly diminish the resistive losses at tunnel junctions and contacts, which may be important when the device is operating under high solar concentration (>500 suns). Narrowing the wavelength range over which the photons are optimally absorbed may also simplify the design of the antireflective coating. Additionally, InP is radiation-resistant, and the use of In-rich AlₓIn₁₋ₓP alloys for the top sub-cell may improve the performance of these multijunction photovoltaic devices in space applications.

As mentioned above, the sub-cells may be grown strain-free on a GaAs or Ge substrate through the use of an intermediate transitional buffer layer to bridge the gap in the lattice constants of the epitaxial sub-cell layers and the substrate. GaAs and Ge are the primary choices for the bulk substrate used in the presently described exemplary embodiment, because the lattice-mismatch to the sub-cell layers is relatively small. The total lattice-mismatch between the substrate and sub-cell layers ranges from approximately 0.009 for a=0.5725 nm to approximately 0.026 for a=0.58 nm. Use of a GaAs or Ge bulk substrate would also place growth of the buffer in compression (final a>starting a) rather than in tension (final a<starting a), which aids in dislocation control and crack mitigation. According to an embodiment, growth on Ge may have the added advantage that it may also form a very low bandgap (E_{g}=0.7 eV) bottom sub-cell that will contribute additional voltage to the device. This situation is mentioned above where the top sub-cell is lattice-matched to intermediate sub-cells, but not to the bottom sub-cell. Therefore, it should be appreciated that in some embodiments, the substrate actually comprises a bottom sub-cell. In other embodiments, the bottom sub-cell may comprise a separate component that is coupled to the substrate. GaₓIn₁₋ₓAs is a potential choice for the buffer layer material, since it yields readily under strain and therefore provides some degree of control over dislocation formation. According to another exemplary embodiment, the use of a Si substrate is also possible, with lattice-mismatch between the substrate and sub-cell layers- on the order of 0.055. Persons skilled in the art of transitional buffer growth could envision other substrate/buffer combinations as well, some of which are listed above.

According to an exemplary embodiment, growth of a photovoltaic device in which all sub-cells are lattice-matched to one another, with the possible exception of the very bottom sub-cell, can provide flexibility in the orientation in which the device is grown. According to one exemplary embodiment, the structure may be grown from bottom to top, as shown in FIG. 3, thereby eliminating the need for more complicated fabrication steps. The thicknesses of the various layers of the multijunction photovoltaic device 300 are greatly exaggerated in the figure for illustrative purposes only and should in no way limit the scope of the present embodiment and the claims directed thereto.

FIGS. 3-6 show schematics of photovoltaic devices 300, 400, and 600 in a very simple form merely to illustrate the relative positions of various layers of the devices. Those skilled in the art will readily recognize additional components that are omitted from the figures to simplify the drawings.

In FIG. 3, the multijunction photovoltaic device 300 comprises a substrate 301. The substrate 301 may comprise a growth substrate or the final Ge or GaAs substrate. According to the embodiment shown in FIG. 3, the substrate 301 also comprises the device's bottom sub-cell. Above the substrate 301 is a transitional buffer 302 as described. According to an embodiment, attached to the step-graded buffer 302 is one or more intermediate sub-cells 303a-303c followed by the top sub-cell 304. According to an embodiment, the top sub-cell 304 is lattice matched to the one or more intermediate sub-cells 303a-303c. However, the top sub-cell 304 and the intermediate sub-cells 303a-303c are not lattice-matched to the bottom sub-cell/substrate 301. Thus, the transitional buffer 302 can transition between the different lattice constants between the lowest intermediate sub-cell 303a and the bottom sub-cell/substrate 301 to reduce strain.

In another variation, the device can be grown in an inverted orientation and later moved to a foreign handle, as depicted in FIGS. 4 & 5, which may enable other specific advantages. According to the embodiment shown in FIG. 4, the multijunction photovoltaic device 400 comprises a growth substrate 401. A transitional buffer 402 can be provided between the growth substrate 401 and the top sub-cell 304. Following the top sub-cell 304 are one or more intermediate sub-cells 303c-303a. As in the previous embodiments, the top sub-cell 304 is lattice-matched to the one or more intermediate sub-cells 303c-303a. Turning now to FIG. 5, the sub-cells 303a-304 can be released from the growth substrate 401 and bonded to the final substrate 501 so that the top sub-cell 304 is once again on top. In this embodiment, a transitional buffer is not required between the intermediate sub-cells 303a-303c and the final substrate 501.

The embodiments shown in FIGS. 3-5 comprise the situation where the top sub-cell is lattice matched to the intermediate sub-cells, which are all lattice mismatched to the bottom sub-cell/substrate.

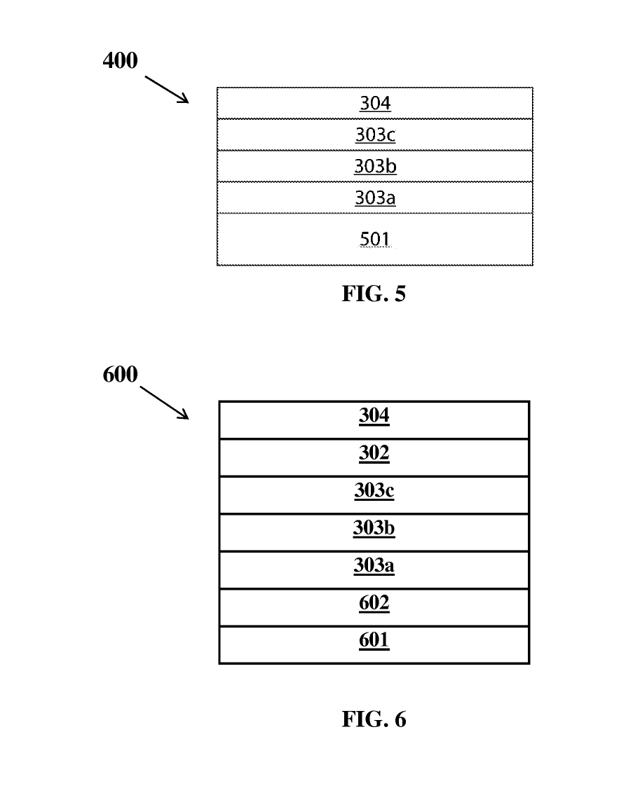

FIG. 6 shows a multi-junction photovoltaic device 600 according to another embodiment. In the embodiment shown in FIG. 6, the device 600 includes a substrate 601 and a bottom sub-cell 602. In the exemplary embodiment, coupled to the bottom sub-cell 602 are the one or more intermediate sub-cells 303a-303c. According to the embodiment shown in FIG. 6, the one or more intermediate sub-cells 303a-303c are lattice matched to both the bottom sub-cell 602 and the substrate 601. According to an embodiment, the transitional buffer 302 can be coupled to the intermediate sub-cell 303c and then the top sub-cell 304 can be coupled to the transitional buffer 302.

Therefore, the embodiment shown in FIG. 6 differs from the previous embodiments in that the top sub-cell 304 is lattice mismatched to the one or more intermediate sub-cells 303a-303c as well as the bottom sub-cell 602 and the substrate 601. However, as can be appreciated, an exemplary implementation still only requires a single transitional buffer 302.

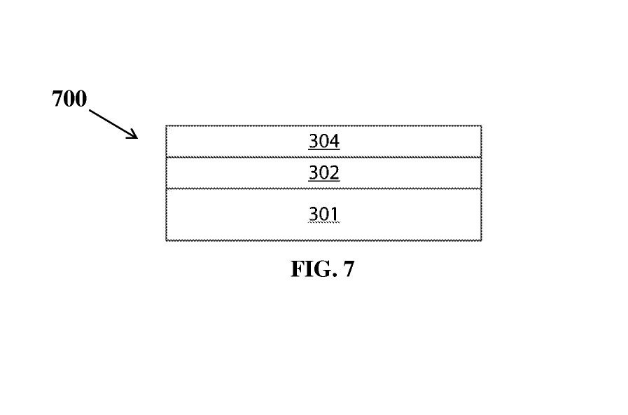

While the above discussion has primarily been focused on multijunction photovoltaic devices, it should be appreciated that the present exemplary embodiment is equally applicable to single-junction photovoltaic devices as shown in FIG. 7.

FIG. 7 shows an exemplary single-junction photovoltaic device 700. While the above discussion has been limited to multijunction photovoltaic devices, it should be appreciated that Aluminum may be substituted for Gallium in single-junction photovoltaic devices as well. For example, in FIG. 7, the single-junction photovoltaic device 700 comprises a substrate 301, a transitional buffer layer 302, and a top p-n junction 304. According to the preferred embodiment, the p-n junction 304 may comprise an AlₓIn₁₋ₓP alloy, for example. Consequently, the claims that follow should not be limited to multijunction photovoltaic devices. Unlike prior art single-junction photovoltaic devices that may use a GaₓIn₁₋ₓP alloy for the p-n junction and thus, is already lattice-matched to the substrate, the p-n junction 304 in the embodiment shown in FIG. 7 is lattice-mismatched to the substrate 301 and thus, requires the transitional buffer layer 302.

Design of the photovoltaic devices as taught herein may encompass any existing variant of which light absorption, current extraction, quantum efficiency, heat dissipation, among other advantages, may be optimized.

In addition to completely monolithic devices, the high bandgaps of AlₓIn₁₋ₓP make it ideal for high efficiency spectral splitting, mechanical stacking or bonding applications, which combine sub-cells grown on several different substrates. A high bandgap AlₓIn₁₋ₓP p-n junction could also function as a stand-alone photovoltaic device.

The embodiments described above may provide a variety of advantages in numerous applications. For example, in one embodiment, the AlₓIn₁₋ₓP-based alloys may be used to increase the bandgap of the top sub-cell to the ideal values for multijunction devices with four or more sub-cells. Operation of the device at high voltages and low currents may improve its performance under high solar concentration conditions. The use of InP-rich alloys may increase the radiation resistance of the device for space applications. According to another embodiment, the intermediate sub-cells of a monolithic multijunction PV device using an AlₓIn₁₋ₓP top cell, with exception of the very bottom cell in some instances, may be composed of materials with optimal direct bandgap energies that are lattice-matched to one another. This approach may eliminate the need for multiple intermediate buffers that bridge the gap in lattice constants between sub-cells with different lattice constants to improve material quality. According to yet another embodiment, sub-cells may be grown strain free on a GaAs or Ge bulk substrate utilizing a single transitional buffer layer grown in compression rather than in tension, which may prevent crack formation in the epitaxial sub-cell layers. GaₓIn₁₋ₓAs is a possible choice for the buffer. Ge may also be used to form a low bandgap (E_{g}=0.7 eV) bottom sub-cell.

While a number of exemplary aspects and embodiments have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

We claim:

1. A multijunction photovoltaic device, comprising:
a substrate;
one or more intermediate sub-cells coupled to the substrate; and
a top sub-cell comprising an AlₓIn₁₋ₓP alloy coupled to the one or more intermediate sub-cells and lattice mismatched to the substrate.

2. The multijunction photovoltaic device of claim 1, wherein the one or more intermediate sub-cells are lattice-mismatched to the substrate and the top sub-cell is lattice matched to the one or more intermediate sub-cells.

3. The multijunction photovoltaic device of claim 1, further comprising a transitional buffer layer positioned between the substrate and the one or more intermediate sub-cells.

4. The multijunction photovoltaic device of claim 1, wherein each of the one or more intermediate sub-cells comprises a bandgap lower than the bandgap of the AlₓIn₁₋ₓP top sub-cell.

5. The multijunction photovoltaic device of claim 3, wherein the AlₓIn₁₋ₓP top sub-cell has a bandgap greater than 1.75 eV.

6. The multijunction photovoltaic device of claim 1, further comprising a bottom sub-cell comprising an alloy including germanium or gallium arsenide positioned between the substrate and the one or more intermediate sub-cells.

7. The multijunction photovoltaic device of claim 6, further comprising a transitional buffer layer positioned between the bottom sub-cell and the one or more intermediate sub-cells and wherein the bottom sub-cell is lattice-matched to the substrate and lattice mismatched to the one or more intermediate sub-cells.

8. A single junction photovoltaic device, comprising:
a substrate;
a transitional buffer layer coupled to the substrate; and
a p-n junction comprising an AlₓIn₁₋ₓP alloy coupled to the transitional buffer layer.

9. The single junction photovoltaic device of claim 8, wherein the substrate and the p-n junction are lattice mismatched to one another.

10. The single junction photovoltaic device of claim 8, wherein the substrate comprises GaAs and wherein the transitional buffer layer is grown in compression.

11. The single junction photovoltaic device of claim 7, wherein the substrate comprises Ge and wherein the transitional buffer layer is grown in compression.

12. The single junction photovoltaic device of claim 7, wherein the p-n junction has a bandgap greater than 1.75 eV.

13. A method for forming a multijunction photovoltaic device, comprising the steps of:
providing a substrate;
forming one or more intermediate sub-cells on top of the substrate; and
forming a top sub-cell comprising an AlₓIn₁₋ₓP alloy on top of the one or more intermediate sub-cells that is lattice mismatched to the substrate.

14. The method of claim 13, wherein the step of forming the top sub-cell comprises forming the top sub-cell that is lattice matched to the one or more intermediate sub-cells.

15. The method of claim 13, further comprising a step of positioning a transitional buffer layer between the substrate and the one or more intermediate sub-cells.

16. The method of claim 13, wherein the steps of forming the one or more intermediate sub-cells and forming the top sub-cell comprises forming each of the one or more intermediate sub-cells having a bandgap lower than the bandgap of the AlₓIn₁₋ₓP top sub-cell.

17. The method of claim 16, wherein the step of forming the top sub-cell comprises forming the top sub-cell with a bandgap greater than 1.75 eV.

18. The method of claim 13, further comprising a step of forming a bottom sub-cell comprising an alloy including germanium or gallium arsenide positioned between the substrate and the one or more intermediate sub-cells.

19. The method of claim 18, further comprising a step of positioning a transitional buffer layer between the bottom sub-cell and the one or more intermediate sub-cells and wherein the bottom sub-cell is lattice-matched to the substrate and lattice mismatched to the one or more intermediate sub-cells.

20. A method for forming a single junction photovoltaic device, comprising the steps of:
providing a substrate;
coupling a transitional buffer layer to the substrate; and
forming a p-n junction comprising an AlₓIn₁₋ₓP alloy coupled to the transitional buffer layer.

21. The method of claim 20, wherein the substrate and the p-n junction are lattice mismatched to one another.

22. The method of claim 20, wherein the substrate comprises GaAs and the step of coupling the transitional buffer layer comprises growing the transitional buffer layer in compression.

23. The method of claim 20, wherein the substrate comprises Ge and the step of coupling the transitional buffer layer comprises growing the transitional buffer layer in compression.

24. The method of claim 20, wherein the step of forming the p-n junction comprises forming the p-n junction with a bandgap greater than 1.75 eV.
